(19) United States
(12) Patent Application Publication
(10) Pub. No.: US 2024/0372041 A1
(43) Pub. Date: Nov. 7, 2024

(54) DISPLAY DEVICE COMPRISING SEMICONDUCTOR LIGHT-EMITTING ELEMENT

(71) Applicant: LG ELECTRONICS INC., Seoul (KR)

(72) Inventors: Byoungkwon CHO, Seoul (KR); Jaehyuk LEE, Seoul (KR); Wonseok CHOI, Seoul (KR); Chilkeun PARK, Seoul (KR)

(73) Assignee: LG ELECTRONICS INC., Seoul (KR)

(21) Appl. No.: 18/685,024

(22) PCT Filed: Aug. 20, 2021
(86) PCT No.: PCT/KR2021/011120

§ 371 Date: Feb. 20, 2024

(51) Int. Cl. H01L 33/42; H01L 25/075; H01L 33/54; H01L 33/62

(52) U.S. Cl. CPC H01L 33/42; H01L 25/0753; H01L 33/54; H01L 33/62

(57) ABSTRACT

A lens driving device according to an embodiment includes a substrate, a first frame including a lens and disposed on the substrate, a second frame on which the first frame is placed and a third frame on which the second frame is disposed. The first frame may move in a Z-axis direction, the second frame may tilt in X-axis and Y-axis directions and rotate around the Z axis, and the third frame may include a stopper structure to limit tilting and rotation of the second frame.

### TECHNICAL FIELD

An embodiment relates to a semiconductor light emitting device and a display device including the same.

### Background Art

Large-area displays include liquid crystal displays (LCDs), OLED displays, and Micro-LED displays.

Micro-LED display is a display that uses micro-LED, a semiconductor light emitting device with a diameter or cross-sectional area of 100 μm or less, as a display device.

Micro-LED displays use micro-LED, a semiconductor light emitting device, as a display device, so they have excellent performance in many characteristics such as contrast ratio, response speed, color reproduction rate, viewing angle, brightness, resolution, lifespan, luminous efficiency, and luminance.

In particular, the micro-LED display has the advantage of being able to freely adjust the size and resolution and implement a flexible display because the screen may be separated and combined in a modular manner.

However, because large micro-LED displays require more than millions of micro-LEDs, there is a technical problem that makes it difficult to quickly and accurately transfer micro-LEDs to the display panel.

Transfer technologies that have been recently developed include the pick and place process, laser lift-off method, or self-assembly method.

Among these, the self-assembly method is a method in which the semiconductor light emitting device finds its assembly position within the fluid on its own, and is an advantageous method for implementing a large-screen display device.

Recently, U.S. Pat. No. 9,825,202 proposed a micro-LED structure suitable for self-assembly, but there is still insufficient research on technology for manufacturing displays through self-assembly of micro-LEDs.

In particular, in the case of rapidly transferring millions of semiconductor light emitting devices to a large display in the prior art, the transfer speed may be improved, but there is a technical problem that the transfer error rate may increase and the transfer yield may be lowered.

Meanwhile, in related technologies, a self-assembly transfer process using dielectrophoresis (DEP) is being attempted, but there is a problem with a low self-assembly rate due to the non-uniformity of the DEP force.

In addition, in related technologies, there is a problem that the lighting rate is reduced due to a decrease in electrical contact characteristics between the electrodes of the self-assembly light emitting device and the predetermined panel electrode.

### DISCLOSURE

### Technical Problem

One of the technical objects of the embodiment is to solve the problem of low self-assembly rate due to non-uniformity of DEP force in self-assembly method using dielectrophoresis (DEP).

In addition, one of the technical objects of the embodiment is to solve the problem of a decrease in the lighting rate due to a decrease in the electrical contact characteristics between the electrodes of the self-assembly light emitting device and the predetermined panel electrode.

The technical objects of the embodiments are not limited to those described in this item and include those that can be understood through the entire specification.

### Technical Solution

A display device having a semiconductor light emitting device according to the embodiment may include a light emitting part including a first conductivity type semiconductor layer, an active layer and a second conductivity type semiconductor layer, an upper electrode layer disposed on the light emitting part, a lower electrode layer disposed below the light emitting part, a translucent electrode layer disposed between the light emitting part and the lower electrode layer and a pad electrode disposed below the translucent electrode layer and physically contacted.

The surface of the translucent electrode layer may be hydrophilic.

The translucent electrode layer may have a higher melting point than the lower electrode layer.

The translucent electrode layer may include a semiconductor light emitting device treated with O₂ plasma or Ar plasma.

The thickness of the translucent electrode layer may be thinner than the thickness of the lower electrode layer.

The translucent electrode layer may include at least one of ITO (indium tin oxide), IAZO (indium aluminum zinc oxide), IZO (indium zinc oxide), IZTO (indium zinc tin oxide), IGZO (indium gallium zinc oxide), IGTO (indium gallium tin) oxide), aluminum zinc oxide (AZO), antimony tin oxide (ATO), gallium zinc oxide (GZO), IZO nitride (IZON), Al—Ga ZnO (AGZO), or In—Ga ZnO (IGZO).

The translucent electrode layer may be formed to have a thickness of 10 nm to 100 nm. The translucent electrode layer may be formed to have a thickness of 30 nm to 60 nm.

An adhesive metal layer may be further included between the light emitting part and the translucent electrode layer.

A magnetic layer may be further included between the light emitting part and the translucent electrode layer.

The embodiment may further include a passivation layer on the light emitting part.

The passivation layer may include a protruding passivation layer that overlaps the center of the light emitting part and the top and bottom.

Additionally, the embodiment may further include a first assembly wiring disposed under the translucent electrode layer and a second assembly wiring disposed under the translucent electrode layer and spaced apart from the first assembly wiring.

The second assembly wiring may be arranged at a different height from the first assembly wiring.

### Advantageous Effects

According to the semiconductor light emitting device and the display device including the same according to the embodiment, the self-assembly method using dielectrophoresis (DEP) has the technical effect of solving the problem of low self-assembly rate due to non-uniformity of DEP force.

For example, in the embodiment, translucent electrode provided on the light emitting device chip has a dielectric constant and thus serves as a dielectric film, so the DEP force is improved, which has a heterogeneous and special technical effect that can improve the assembly rate.

In addition, the light emitting device to which the embodiment is applied has a technical effect of significantly improving the assembly rate of the light emitting device chip in the assembly hole by distributing the DEP force at the bottom of the light emitting device chip evenly due to the lower electrode layer having a flat surface characteristic due to the translucent electrode layer.

In addition, according to the embodiment, there is a technical effect of solving the problem of a decrease in the lighting rate due to a decrease in the electrical contact characteristics between the electrode of the self-assembly light emitting device and the predetermined panel electrode.

For example, according to the embodiment, there is a technical effect of significantly improving the surface morphology of the rear bonding metal by forming a translucent electrode layer between the epitaxial layer (GaN) of the semiconductor light emitting device (chip) and the lower bonding metal. Accordingly, according to the embodiment, the contact characteristics between the rear metal of the light emitting device and the panel wiring are significantly improved, resulting in a technical effect of solving lighting defects.

The technical effects of the embodiments are not limited to those described in this item and include those that can be understood throughout the specification.

### DESCRIPTION OF DRAWINGS

FIG. 1 is an exemplary diagram of a living room of a house where a display device according to an embodiment is placed.

FIG. 2 is a block diagram schematically showing a display device according to an embodiment.

FIG. 3 is a circuit diagram showing an example of the pixel of FIG. 2.

FIG. 4 is an enlarged view of the first panel area in the display device of FIG. 1.

FIG. 5 is a cross-sectional view taken along line B1-B2 in area A2 of FIG. 4.

FIG. 6 is an example of a light emitting device according to an embodiment being assembled on a substrate by a self-assembly method.

FIG. 7 is a plan view showing a display device according to an embodiment.

FIG. 8 is a cross-sectional view of the display device according to the embodiment shown in FIG. 7.

FIG. 9 is a distribution diagram of an electric field when a pad is provided.

FIG. 10 is a cross-sectional view showing a semiconductor light emitting device of an example.

FIGS. 11A to 11D are photos of internal technology related to the display panel.

FIGS. 12A to 12C are data for a micro LED display according to an embodiment.

FIG. 13 is a cross-sectional view of a second semiconductor light emitting device applied to a display panel according to an embodiment.

FIG. 14 is a cross-sectional view of a second display device according to an embodiment.

### MODE FOR INVENTION

Hereinafter, the embodiment disclosed in this specification will be described in detail with reference to the attached drawings. The suffixes ‘module’ and ‘part’ for elements used in the following description are given or used interchangeably in consideration of ease of specification preparation, and do not have distinct meanings or roles in themselves. Additionally, the attached drawings are intended to facilitate easy understanding of the embodiments disclosed in this specification, and the technical idea disclosed in this specification is not limited by the attached drawings. Additionally, when an element such as a layer, region or substrate is referred to as being ‘on’ another component, this includes either directly on the other element or there may be other intermediate elements in between.

Display devices described in this specification may include digital TVs, mobile phones, smart phones, laptop computers, digital broadcasting terminals, personal digital assistants (PDAs), portable multimedia players (PMPs), navigation, slate PCs, tablet PCs, ultra-books, desktop computers, etc. However, the configuration according to the embodiment described in this specification may be applied to a device capable of displaying even if it is a new product type that is developed in the future.

Hereinafter, a light emitting device according to an embodiment and a display device including the same will be described.

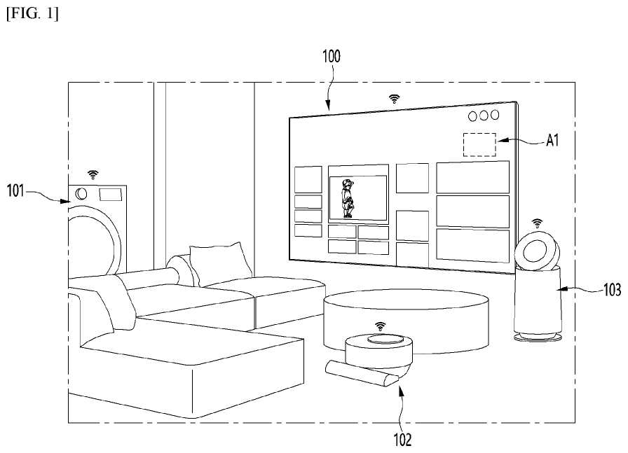

FIG. 1 shows a living room of a house where a display device 100 according to an embodiment is placed.

The display device 100 of the embodiment may display the status of various electronic products such as a washing machine 101, a robot vacuum cleaner 102, and an air purifier 103, and it is possible to communicate with each electronic product based on IoT and control each electronic product based on the user's setting data.

The display device 100 according to the embodiment may include a flexible display manufactured on a thin and flexible substrate. Flexible displays may bend or curl like paper while maintaining the characteristics of existing flat displays.

In a flexible display, visual information may be implemented by independently controlling the light emission of unit pixels arranged in a matrix form. A unit pixel refers to the minimum unit for implementing one color. A unit pixel of a flexible display may be implemented by a light emitting device. In the embodiment, the light emitting device may be Micro-LED or Nano-LED, but is not limited thereto.

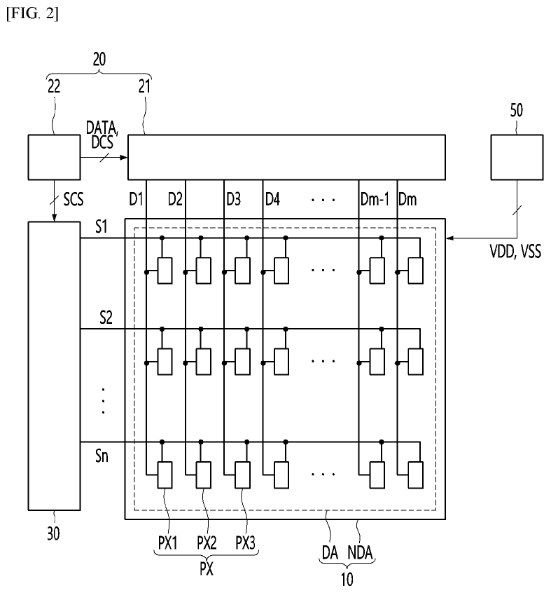

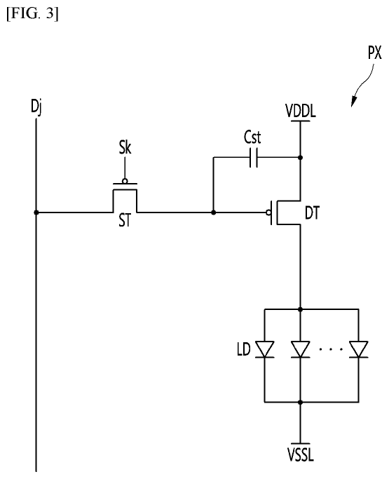

FIG. 2 is a block diagram schematically showing a display device according to the embodiment, and FIG. 3 is a circuit diagram showing an example of the pixel of FIG. 2.

Referring to FIGS. 2 and 3, a display device according to an embodiment may include a display panel 10, a driving circuit 20, a scan driver 30, and a power supply circuit 50.

The display device 100 of the embodiment may drive the light emitting device in an active matrix (AM) method or a passive matrix (PM) method.

The driving circuit 20 may include a data driver 21 and a timing control unit 22.

The display panel 10 may be divided into a display area DA and a non-display area NDA disposed around the display area DA. The display area DA is an area where pixels PX are formed to display an image. The display panel 10 may include a data lines (D1 to Dm, m is an integer greater than 2), a scan lines (S1 to Sn, n is an integer greater than 2) that intersect the data lines D1 to Dm, and a high-potential voltage line supplied with a high-potential voltage,

Each of the pixels PX may include a first sub-pixel PX1, a second sub-pixel PX2, and a third sub-pixel PX3. The first sub-pixel PX1 may emit the first color light of the first wavelength, the second sub-pixel PX2 may emit the second color light of the second wavelength, and the third sub-pixel PX3 may emit the third color light of the third wavelength. The first color light may be red light, the second color light may be green light, and the third color light may be blue light, but are not limited thereto. Additionally, in FIG. 2, it is illustrated that each of the pixels PX may include three sub-pixels, but the present invention is not limited thereto. That is, each pixel PX may include four or more sub-pixels.

Each of the first sub-pixel PX1, the second sub-pixel PX2, and the third sub-pixel PX3 may be connected to at least one of the data lines D1 to Dm and at least one of the scan lines S1 to Sn and a high-potential voltage liens. As shown in FIG. 3, the first sub-pixel PX1 may include light emitting devices LD, a plurality of transistors for supplying current to the light emitting devices LD, and at least one capacitor Cst.

Although not shown in the drawing, each of the first sub-pixel PX1, the second sub-pixel PX2, and the third sub-pixel PX3 may include only one light emitting device LD and at least one capacitor Cst.

Each of the light emitting devices LD may be a semiconductor light emitting diode including a first electrode, a plurality of conductivity type semiconductor layers, and a second electrode. Here, the first electrode may be an anode electrode and the second electrode may be a cathode electrode, but this is not limited.

Referring to FIG. 3, the plurality of transistors may include a driving transistor DT that supplies current to the light emitting devices LD, a scan transistor ST that supplies a data voltage to the gate electrode of the driving transistor DT. The driving transistor DT may include a gate electrode connected to the source electrode of the scan transistor ST, a source electrode connected to a high-potential voltage line to which a high-potential voltage is applied and a drain electrode connected to the first electrodes of the light emitting devices LD. The scan transistor ST may include a gate electrode connected to the scan line (Sk, k is an integer that satisfies 1≤k≤n), a source electrode connected to the gate electrode of the driving transistor DT, and a drain electrode connected to the data line (Dj, j is an integer that satisfies 1≤j≤m).

The capacitor Cst is formed between the gate electrode and the source electrode of the driving transistor DT. The storage capacitor Cst may charge the difference between the gate voltage and the source voltage of the driving transistor DT.

The driving transistor DT and the scan transistor ST may be formed of a thin film transistor. In addition, in FIG. 3, the driving transistor DT and the scan transistor ST are mainly described as being formed of a P-type MOSFET (Metal Oxide Semiconductor Field Effect Transistor), but the present invention is not limited thereto. The driving transistor DT and scan transistor ST may be formed of an N-type MOSFET. In this case, the positions of the source and drain electrodes of the driving transistor DT and the scan transistor ST may be changed.

In addition, Although FIG. 3 illustrates that each of the first sub-pixel PX1, the second sub-pixel PX2, and the third sub-pixel PX3 includes a 2T1C (2 Transistor-1 capacitor) having one driving transistor DT, one scan transistor ST, and one capacitor Cst, the present invention is not limited thereto. Each of the first sub-pixel PX1, the second sub-pixel PX2, and the third sub-pixel PX3 may include a plurality of scan transistors ST and a plurality of capacitors Cst.

Referring again to FIG. 2, the driving circuit 20 outputs signals and voltages for driving the display panel 10. For this purpose, the driving circuit 20 may include a data driver 21 and a timing controller 22.

The data driver 21 receives digital video data DATA and source control signal DCS from the timing control unit 22. The data driver 21 convert digital video data DATA into analog data voltages according to the source control signal DCS and supplies them to the data lines D1 to Dm of the display panel 10.

The timing control unit 22 receives digital video data DATA and timing signals from the host system. Timing signals may include a vertical sync signal, a horizontal sync signal, a data enable signal, and a dot clock. The host system may be an application processor in a smartphone or tablet PC, a monitor, or a system-on-chip in a TV.

The scan driver 30 receives a scan control signal SCS from the timing control unit 22. The scan driver 30 generates scan signals according to the scan control signal SCS and supplies them to the scan lines S1 to Sn of the display panel 10. The scan driver 30 may include a plurality of transistors and may be formed in the non-display area NDA of the display panel 10. Alternatively, the scan driver 30 may be formed as an integrated circuit, and in this case, it may be mounted on a gate flexible film attached to the other side of the display panel 10.

The power supply circuit 50 may generate a high-potential voltage VDD and a low-potential voltage VSS for driving the light emitting devices (LD) of the display panel 10 from the main power supply and supply them to the high-potential voltage line and the low-potential voltage line of the display panel 10. Additionally, the power supply circuit 50 may generate and supply driving voltages for driving the driving circuit 20 and the scan driver 30 from the main power supply.

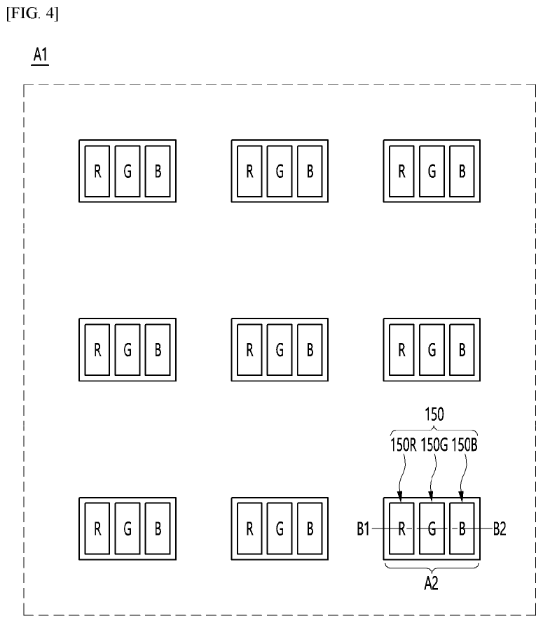

FIG. 4 is an enlarged view of the first panel area A1 in the display device of FIG. 1.

According to FIG. 4, the display device 100 of the embodiment may be manufactured by mechanically and electrically connecting a plurality of panel areas, such as the first panel area A1, by tiling.

The first panel area A1 may include a plurality of light emitting devices 150 arranged for each unit pixel (PX in FIG. 2).

For example, the unit pixel PX may include a first sub-pixel PX1, a second sub-pixel PX2, and a third sub-pixel PX3. For example, a plurality of red light emitting devices 150R are disposed in the first sub-pixel PX1, a plurality of green light emitting devices 150G are disposed in the second sub-pixel PX2, and a plurality of blue light emitting devices 150B may be placed in the third sub-pixel PX3. The unit pixel PX may further include a fourth sub-pixel in which no light emitting device is disposed, but this is not limited. Meanwhile, the light emitting device 150 may be a semiconductor light emitting device.

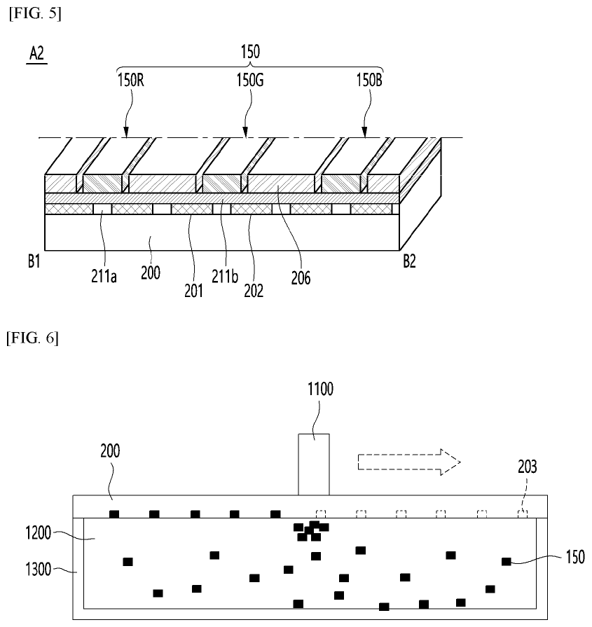

Next, FIG. 5 is a cross-sectional view taken along line B1-B2 in area A2 of FIG. 4.

Referring to FIG. 5, the display device 100 of the embodiment may include a substrate 200, assembly wiring 201 and 202, a first insulating layer 211a, a second insulating layer 211b, a third insulating layer 206 and a plurality of light emitting devices 150.

The assembly wiring may include a first assembly wiring 201 and a second assembly wiring 202 that are spaced apart from each other. The first assembly wiring 201 and the second assembly wiring 202 may be provided to generate dielectrophoretic force to assemble the light emitting device 150. Additionally, the first assembly wiring 201 and the second assembly wiring 202 may be electrically connected to the electrodes of the light emitting device and may function as electrodes of the display panel.

The assembly wirings 201 and 202 may be formed of transparent electrodes (ITO) or may contain a metal material with excellent electrical conductivity. For example, the assembly wirings 201 and 202 may be formed of at least one of titanium (Ti), chromium (Cr), nickel (Ni), aluminum (Al), platinum (Pt), gold (Au), tungsten (W), or molybdenum (Mo) or an alloy thereof.

The first insulating layer 211a may be disposed between the first assembly wiring 201 and the second assembly wiring 202, and the second insulating layer 211b may be disposed on the first assembly wiring 201 and the second assembly wiring 202. The first insulating layer 211a and the second insulating layer 211b may be an oxide film or a nitride film, but are not limited thereto.

The light emitting device 150 may include, but is not limited to, a red light emitting device 150, a green light emitting device 150G, and a blue light emitting device 150B0 to form a sub-pixel, and it is also possible to implement red and green colors by using red phosphors and green phosphors, respectively.

The substrate 200 may be formed of glass or polyimide. Additionally, the substrate 200 may include a flexible material such as PEN (Polyethylene Naphthalate) or PET (Polyethylene Terephthalate). Additionally, the substrate 200 may be made of a transparent material, but is not limited thereto.

The third insulating layer 206 may include an insulating and flexible material such as polyimide, PEN, PET, etc., and may be integrated with the substrate 200 to form one substrate.

The third insulating layer 206 may be a conductive adhesive layer that has adhesiveness and conductivity, and the conductive adhesive layer is flexible and may enable a flexible function of the display device. For example, the third insulating layer 206 may be an anisotropic conductive film (ACF) or a conductive adhesive layer such as an anisotropic conductive medium or a solution containing conductive particles. The conductive adhesive layer may be a layer that is electrically conductive in a direction perpendicular to the thickness, but electrically insulating in a direction horizontal to the thickness.

The third insulating layer 206 may include an assembly hole 203 into which the light emitting device 150 is inserted (see FIG. 6). Therefore, during self-assembly, the light emitting device 150 may be easily inserted into the assembly hole 203 of the third insulating layer 206. The assembly hole 203 may be called an insertion hole, a fixing hole, an alignment hole, etc.

The gap between the assembly wires 201 and 202 is formed to be smaller than the width of the light emitting device 150 and the width of the assembly hole 203, so that the assembly position of the light emitting device 150 using an electric field may be fixed more precisely.

A third insulating layer 206 is formed on the assembly wirings 201 and 202 to protect the assembly wirings 201 and 202 from the fluid 1200 and leakage of current flowing through the assembly wiring 201 and 202 may be prevented. The third insulating layer 206 may be formed as a single layer or multilayer of an inorganic insulator such as silica or alumina or an organic insulator.

Additionally, the third insulating layer 206 may include an insulating and flexible material such as polyimide, PEN, PET, etc., and may be integrated with the substrate 200 to form one substrate.

The third insulating layer 206 may be an adhesive insulating layer or a conductive adhesive layer with conductivity. The third insulating layer 206 is flexible and may enable a flexible function of the display device.

The third insulating layer 206 has a partition wall, and the assembly hole 203 may be formed by the partition wall. For example, when forming the substrate 200, a portion of the third insulating layer 206 is removed, so that each of the light emitting devices 150 may be assembled into the assembly hole 203 of the third insulating layer 206.

An assembly hole 203 where the light emitting devices 150 are coupled is formed in the substrate 200, and the surface where the assembly hole 203 is formed may be in contact with the fluid 1200. The assembly hole 203 may guide the exact assembly position of the light emitting device 150.

Meanwhile, the assembly hole 203 may have a shape and size corresponding to the shape of the light emitting device 150 to be assembled at the corresponding location. Accordingly, it is possible to prevent another light emitting device from being assembled in the assembly hole 203 or a plurality of light emitting devices from being assembled.

FIG. 6 is a diagram showing an example in which a light emitting device according to the embodiment is assembled on a substrate by a self-assembly method.

The self-assembly method of the light emitting device will be described with reference to FIGS. 5 to 7.

The substrate 200 may be a panel substrate of a display device. In the following description, the substrate 200 will be described as a panel substrate of a display device, but the embodiment is not limited thereto.

Referring to FIG. 6, a plurality of light emitting devices 150 may be input into a chamber 1300 filled with a fluid 1200. The fluid 1200 may be water such as ultrapure water, but is not limited thereto. The chamber may be called a water tank, container, container, etc.

After this, the substrate 200 may be placed on the chamber 1300. Depending on the embodiment, the substrate 200 may be input into the chamber 1300.

As shown in FIG. 5, a pair of assembly wirings 201 and 202 corresponding to each of the light emitting devices 150 to be assembled may be disposed on the substrate 200.

Referring to FIG. 6, after the substrate 200 is disposed, the assembly device 1100 including a magnetic material may move along the substrate 200. For example, a magnet or electromagnet may be used as a magnetic material. The assembly device 1100 may move while in contact with the substrate 200 in order to maximize the area to which the magnetic field is applied within the fluid 1200. Depending on the embodiment, the assembly device 1100 may include a plurality of magnetic materials or a magnetic material of a size corresponding to that of the substrate 200. In this case, the moving distance of the assembly device 1100 may be limited to within a predetermined range.

By the magnetic field generated by the assembly device 1100, the light emitting device 150 in the chamber 1300 may move toward the assembly device 1100.

While moving toward the assembly device 1100, the light emitting device 150 may enter the assembly hole 203 and contact the substrate 200 by a dielectrophoretic force (DEP force).

Specifically, The assembly wirings 201 and 202 form an electric field by an externally supplied power source, and a dielectrophoretic force may be formed between the assembly wirings 201 and 202 by this electric field. The light emitting device 150 may be fixed to the assembly hole 203 on the substrate 200 by this dielectrophoretic force.

An electric field applied by the assembly wiring 201 and 202 formed on the substrate 200 may be prevented from being separated by movement of the assembly device 1100 by the electric field applied by the assembly wiring 201 and 202 formed on the substrate. It According to the embodiment, by using the above-described self-assembly method using an electromagnetic field, the time required to assemble each of the light emitting devices 150 on the substrate 200 may be drastically shortened, so that a large-area, high-pixel display may be implemented more quickly and economically.

At this time, a predetermined solder layer (not shown) is formed between the light emitting device 150 assembled on the assembly hole 203 of the substrate 200 and the assembly electrode, thereby improving the bonding strength of the light emitting device 150.

Next, a molding layer (not shown) may be formed in the assembly hole 203 of the substrate 200. The molding layer may be a transparent resin or a resin containing a reflective material or a scattering material.

Hereinafter, a semiconductor light emitting device display device according to the embodiment for solving technical problems will be described with reference to the drawings.

### EMBODIMENT

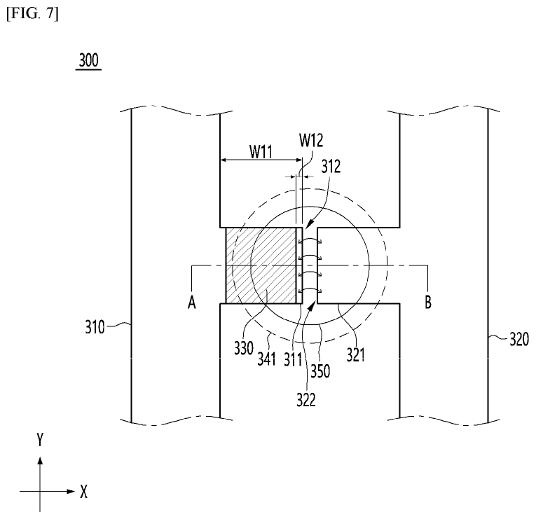

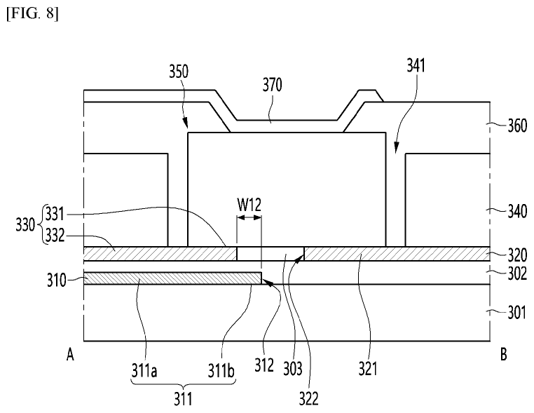

FIG. 7 is a plan view of the display device 300 according to the embodiment, and FIG. 8 is a cross-sectional view taken along line A-B of the display device according to the embodiment shown in FIG. 7.

Referring to FIG. 7, a display device 300 according to the embodiment may include a first wiring 310, a second wiring 320, and a semiconductor light emitting device 350. Additionally, the embodiment may include a pad 330 on the first wiring 310.

Referring to FIG. 8, in the embodiment, the first wiring 310 and the second wiring 320 may be arranged in different layers. For example, the first wiring 310 may be a lower layer, and the second wiring 320 may be an upper layer. For example, the first wiring 310 and the second wiring 320 may not overlap each other. Since the first wiring 310 and the second wiring 320 are disposed on different layers, the first wiring 310 and the second wiring 320 are not short-circuited even if they are adjacent to each other, a high-resolution display may be implemented by minimizing the arrangement gap between the first wire 310 and the second wire 320.

The embodiment may include a pad 330 that is disposed on the same layer as the second wiring 320, is spaced apart from the second wiring 320, and vertically overlaps the first wiring 310.

For example, the pad 330 may cover a portion of the first wiring 310 when viewed from above. For example, a portion of the first wiring 310 adjacent to the second wiring 320 may not be covered by the pad 330. In this case, an electric field may not be formed between the second wiring 320 and another part of the first wiring 310 covered by the pad 330 during self-assembly.

The electric field may be formed between the second wiring 320 and a portion of the first wiring 310 that is not covered by the pad 330. Therefore, the dispersion of the electric field throughout the first wiring 310 is alleviated when the pad 330 is provided compared to when the pad 330 is not provided, and the semiconductor light emitting device 350 may be positioned at the midpoint between the first and second wirings 310 and 320 due to the alleviated electric field in this way.

For example, when the assembly hole 341 is formed to cover the first wiring 310 and the second wiring 320, the semiconductor light emitting device 350 may be disposed on the pad 330 and the second wiring 320 in the assembly hole 341. At this time, the semiconductor light emitting device 350 may be located at the center of the assembly hole 341.

As shown in FIGS. 7 and 8, when the first wiring 310 and the second wiring 320 have a first extension portion 311 and a second extension portion 321, respectively, the assembly hole 341 may be formed to cover the first extension part 311 and the second extension part 321. In this case, the semiconductor light emitting device 350 may be disposed on the pad 330 and the second extension portion 321 within the assembly hole 341. The extension portion may be called a protrusion, a protrusion, etc.

The first extension portion 311 of the first wiring 310 extends toward the second wiring 320 along a first direction (x-axis direction), the second extension portion 321 of the second wiring 320 may extend toward the first wiring 310 along a direction (-x-axis direction) opposite to the first direction (x-axis direction).

The pad 330 may vertically overlap the first extension portion 311. The semiconductor light emitting device 350 may be disposed on the pad 330 and the second extension portion 321 within the assembly hole 341.

According to the embodiment, an electric field is prevented from dispersing between the first wiring 310 or a portion of the first extension portion 311 and the second wiring 320 or the second extension portion 321, and the semiconductor light emitting device 350 may be located at the center of the assembly hole 341 by concentrating an electric field between the first end 312 of the first wiring 210 and the second end 321 of the second wiring 320 by the pad.

Through this, the assembly rate can be increased and the bonding force is strengthened to prevent the semiconductor light emitting device 350 from breaking away, by increasing the contact area between the semiconductor light emitting device 350 and the second wiring 320, it is possible to implement a high-brightness display by improving light efficiency, and image quality may be improved by eliminating the luminance deviation between each pixel.

In particular, when the pad 330 and the second wiring 320 or the second extension portion 321 are electrically connected after self-assembly, electrical signals are supplied to the semiconductor light emitting device 350 from more various locations, light efficiency may be further improved.

The first wiring 310, the second wiring 320, and the pad 330 may be made of metal with excellent electrical conductivity. For example, the first wiring 310, the second wiring 320, and the pad 330 may be made of the same type of metal. For example, the first wiring 310, the second wiring 320, and the pad 330 may have a single-layer or multi-layer structure. For example, the first wiring 310, the second wiring 320, and the pad 330 may have a multilayer structure of Mo/Al/Mo, but this is not limited. Al may be an electrode wiring, and Mo may be an oxidation prevention film.

For example, the second wiring 320 and the pad 330 may be made of the same type of metal.

The first extension portion 311 may include a first extension area 311a and a second extension area 311b. The first extension area extends toward the second wiring 320 and may vertically overlap the pad 330. The second extension area extends from the first extension area toward the second wiring 320 and may not vertically overlap the pad 330.

Referring to FIG. 8, in the embodiment, the pad 330 may include a first pad area 331 and a second pad area 332. The first pad area 331 may vertically overlap the assembly hole 341, and the second pad area 332 may not overlap the assembly hole 341. That is, the second pad area 332 may vertically overlap a partition wall 340. For example, the portion of the pad 330, i.e., the first pad area 331, may be disposed to vertically overlap the assembly hole 341, and the other portion, i.e., the second pad area 332, may be disposed to vertically overlap the partition wall 340. At this time, the area (or size) of the first pad area 331 may be larger than the area (or size) of the second pad area 332.

The embodiment may include a pad 330 to increase the contact area between the semiconductor light emitting device and the second wiring. Accordingly, the semiconductor light emitting device can be more strongly bonded to the second wiring, thereby preventing the semiconductor light emitting device from being separated. In addition, electrical signals are more smoothly supplied to the semiconductor light emitting device through the second wiring, thereby improving the optical efficiency of the semiconductor light emitting device and realizing high brightness.

In particular, when the pad is electrically connected to the second wiring after self-assembly, electrical signals may be supplied not only through the second wiring but also through the pad, allowing current to flow in a wider area of the semiconductor light emitting device, thereby significantly improving optical efficiency and enabling improved high-resolution. In addition, since the semiconductor light emitting device in each pixel is located at the center of the assembly hole, uniform luminance may be secured without luminance deviation between each pixel, improving image quality and product reliability.

Next, referring to FIGS. 7 and 8, the width W12 of the second extension area along the first direction (x-axis direction) may be 0 to 50% of the width W11 of the first extension portion 311 along the first direction (x-axis direction). The fact that the width W12 of the second extension area in the first direction (x-axis direction) is 0 means that one end of the pad 330 and the second end 322 of the second extension area are vertically aligned.

Meanwhile, when the width W12 of the second extension area in the first direction (x-axis direction) exceeds 50% of the width W11 of the first extension portion 311 in the first direction (x-axis direction), as the rate at which an electric field is concentrated on the first wiring 310 increases, the semiconductor light emitting device 350 may be biased toward the first wiring 310 within the assembly hole 341.

Meanwhile, the first extension portion 311, the first wiring 310, the second extension portion 321, the second wiring 320, and the pad 330 may be made of metal with excellent electrical conductivity. The first extension portion 311, the first wiring 310, the second extension portion 321, the second wiring 320, and the pad 330 may be made of the same metal, but this is not limited. For example, the first extension portion 311, the first wiring 310, the second extension portion 321, the second wiring 320, and the pad 330 may have a three-layer structure of Mo/Al/Mo, there is no limitation to this. Al may be an electrode that supplies an electrical signal, and Mo may be an anti-corrosion layer that prevents corrosion of the electrode, but this is not limited.

Next, as shown in FIGS. 7 and 8, around the first end 312 of the first extension portion 311 adjacent to the second end 322 of the second extension portion 321, that is, the second extension area 311b may not vertically overlap the first pad area 331 of the pad 330. Accordingly, an electric field is generated between the second extension area 311b of the first extension part 311 and the second extension part 321, an electric field may not be generated or may be weakly generated between the first extension area 311a and the second extension part 321 of the first extension part 311. Therefore, only the first extension area of the first extension portion 311 is vertically overlapped by the pad 330 to alleviate the concentration of an electric field on the first extension portion 311, thereby allowing the semiconductor light emitting device 350 to be installed in the assembly hole 341. In addition, only the first extension area of the first extension part 311 is vertically overlapped by the pad 330, the semiconductor light emitting device 350 may be assembled in the assembly hole 341 by allowing the second extension area of the first extension part 311 to generate an electric field together with the second extension part 321.

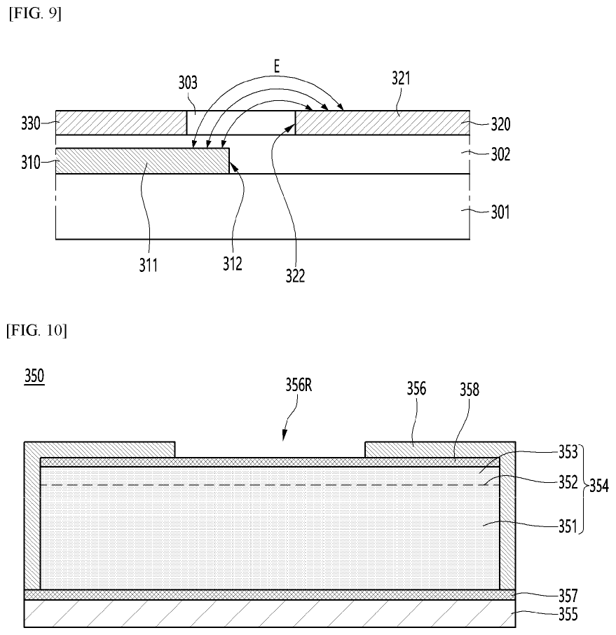

Next, FIG. 9 is a distribution diagram of an electric field when the pad is provided.

Referring briefly to FIG. 8, the display device 300 according to the embodiment may include a substrate 301, a first and second dielectric layers 302 and 303, a first and second extensions 311 and 321, a partition wall 340, a molding layer 360, a semiconductor light emitting device 350, and an upper wiring electrode 370.

The first wiring 310 and the second wiring 320 may be assembly wiring for assembling the semiconductor light emitting device 350. When an alternating current signal is applied to the first wire 310 and the second wire 320, an electric field is generated between the first wiring 310 and the second wiring 320, and the semiconductor light emitting device 350 may be assembled in the assembly hole 341 by a dielectrophoretic force caused by the generated electric field.

Meanwhile, as shown in FIG. 8, the first wiring 310 and the second wiring 320 are not arranged on the same layer but are arranged offset from each other, an electric field generated between the first extension part 311 and the second extension part 321 may be dispersed and distributed on the first extension part 311 disposed below the second extension part 321. Accordingly, an electric field may be distributed throughout the first extension portion 311, so that the semiconductor light emitting device 350 within the assembly hole 341 may be biased toward the first extension portion 311 rather than the center of the assembly hole 341. In this case, internal research has shown that the contact area of the lower surface of the semiconductor light emitting device 350 with the second extension portion 321 may be reduced or no longer in contact, causing various problems.

Alternatively, as the contact area of the semiconductor light emitting device 350 with the second extension portion 321 decreases, the semiconductor light emitting device 350 may not be stably bonded to the second extension portion 321, and the semiconductor light emitting device 350 may be separated from the assembly hole 341.

For example, when the contact area of the semiconductor light emitting device 350 with the second extension portion 321 is reduced, since electrical signals are not smoothly supplied to the semiconductor light emitting device 350 through the second extension portion 321, the light efficiency of the semiconductor light emitting device 350 may decrease and the luminance of the pixel equipped with the semiconductor light emitting device 350 may decrease. These issues were studied internally.

Additionally, when the semiconductor light emitting device 350 is not in contact with the second extension portion 321, since the electrical signal is not supplied to the semiconductor light emitting device 350 through the second extension portion 321, the semiconductor light emitting device 350 does not emit light. Accordingly, internal research has shown that lighting defects may occur in display devices where some pixels do not light up.

In the embodiment, there is technical effect that the pad 330 is arranged to overlap the first extension portion 311 perpendicularly, thereby reducing the overall dispersion of an electric field on the first extension portion 311 and an electric field (E) is concentrated at the center of the assembly hole 341.

Accordingly, the semiconductor light emitting device 350 may be located in the correct position within the assembly hole 341, that is, at the center of the assembly hole 341. In this way, by positioning the semiconductor light emitting device 350 at the center of the assembly hole 341, the contact area between the semiconductor light emitting device 350 and the second extension portion 321 may be increased. The contact area between the semiconductor light emitting device 350 and the second extension portion 321 may be increased.

Due to the increase in the contact area, the semiconductor light emitting device 350 is more strongly bonded to the second extension portion 321, thereby preventing the semiconductor light emitting device 350 from being separated. In addition, electrical signals are more smoothly supplied to the semiconductor light emitting device 350 through the second extension portion 321, thereby improving the optical efficiency of the semiconductor light emitting device 350 and realizing high brightness. In particular, when the pad 330 is electrically connected to the second extension part 321 after self-assembly, electrical signals may be supplied not only through the second extension part 321 but also through the pad 330, so that the current (I) flows in a wider area of the semiconductor light emitting device 350, thereby light efficiency has been significantly improved, enabling even improved high resolution.

The partition wall 340 and the molding layer 360 may be a conductive adhesive layer having adhesiveness and conductivity, and the conductive adhesive layer may be flexible and enable a flexible function of the display device 300. For example, the partition wall 340 and the molding layer 360 may be an anisotropic conductive film (ACF) or a conductive adhesive layer such as an anisotropic conductive medium or a solution containing conductive particles. The conductive adhesive layer may be a layer that is electrically conductive in a direction perpendicular to the thickness, but electrically insulating in a direction horizontal to the thickness.

Meanwhile, the upper wiring electrode 370 may be disposed on the molding layer 360. For example, the upper wiring electrode 370 is a member that supplies an electrical signal to the semiconductor light emitting device 350, and may be electrically connected to the upper side of the semiconductor light emitting device 350. That is, after the molding layer 360 on the upper side of the semiconductor light emitting device 350 is removed to form a contact hole, the upper wiring electrode 370 may be electrically connected to the upper side of the semiconductor light emitting device 350 through a contact hole in the molding layer 360.

Meanwhile, the lower side of the semiconductor light emitting device 350 may be electrically connected to the second wiring 320. Accordingly, the second wiring 320 may be a lower wiring electrode for supplying an electrical signal to the semiconductor light emitting device 350. After the semiconductor light emitting device 350 is assembled in the correct position in the assembly hole 341 by the dielectrophoretic force between the first wiring 310 and the second wiring 320, the lower side of the semiconductor light emitting device 350 may be electrically connected to the second wiring 320 through a bonding process. The lower side of the semiconductor light emitting device 350 and the second wiring 320 may be in face-to-face contact. For example, by applying a positive (+) voltage is supplied to the upper side of the semiconductor light emitting device 350 through the upper wiring electrode 370, and a negative voltage or ground to the lower side of the semiconductor light emitting device 350 through the second wiring 320, light may be generated in the light emitting part 354 by the current (I) flowing through the semiconductor light emitting device 350.

According to the embodiment, the second wiring 320 is not only an upper assembly wiring for assembling the semiconductor light emitting device 350, but also may be a lower wiring electrode that supplies an electrical signal to make the semiconductor light emitting device 350 emit light. Accordingly, there is no need to provide separate wiring for supplying electrical signals to the semiconductor light emitting device 350, so the structure may be simple. In addition, there is no need to provide a separate wiring to supply an electrical signal to the semiconductor light emitting device 350, so the gap between the first wiring 310 and the second wiring 320 may be further narrowed, even if the pixel size becomes smaller to implement high resolution, it is possible to design the first and second wires 310 and 320 to sufficiently correspond to this.

Meanwhile, the pad 330 may also be a lower wiring electrode for supplying an electrical signal to the semiconductor light emitting device 350. To this end, after the semiconductor light emitting device 350 is assembled in the assembly hole 341, the pad 330 and the second wiring 320 may be electrically connected.

Since the pad 330 is located on the other side, that is, on the left side, below the semiconductor light emitting device 350, when an electrical signal is supplied to the semiconductor light emitting device 350 by the pad 330 and the second wiring 320, light is generated in all areas of the semiconductor light emitting device 350, so light emission efficiency may be improved by the current (I) flowing from the upper wiring electrode 370 to the second wiring 320 and the current (I) flowing from the upper wiring electrode 370 to the pad 330, light is generated in all areas of the semiconductor light emitting device 350, so light emission efficiency may be improved. By improving luminous efficiency, luminance is improved and high luminance may be obtained.

Next, FIG. 10 is a cross-sectional view of a semiconductor light emitting device applied to a display panel according to an embodiment.

The semiconductor light emitting device 350 according to the embodiment may include a light emitting portion 354, a lower electrode layer 355, and a passivation layer 356. Additionally, the embodiment may include a translucent electrode layer 357 between the lower electrode layer 355 and the light emitting part 354.

The light emitting part 354 is a member that generates light and may include a first conductivity type semiconductor layer 351, an active layer 352, and a second conductivity type semiconductor layer 353. The first conductivity type semiconductor layer 351, the active layer 352, and the second conductivity type semiconductor layer 353 may be made of a compound semiconductor material. For example, the compound semiconductor material may be a group 3-5 compound semiconductor material, a group 2-6 compound semiconductor material, etc. For example, the compound semiconductor material may include GaN, InGaN, AlN, AlInN, AlGaN, AlInGaN, InP, GaAs, GaP, or GaInP, etc.

For example, the first conductivity type semiconductor layer 351 may include a first conductivity type dopant, and the second conductivity type semiconductor layer 353 may include a second conductivity type dopant. For example, the first conductivity type dopant may be an n-type dopant such as silicon (Si), and the second conductivity type dopant may be a p-type dopant such as boron (B).

The active layer 352 is a region that generates light, and may generate light with a specific wavelength band depending on the material properties of the compound semiconductor. That is, the wavelength band may be determined by the energy band gap of the compound semiconductor included in the active layer 352. Therefore, depending on the energy band gap of the compound semiconductor included in the active layer 352, the semiconductor light emitting device 350 of the embodiment may generate UV light, blue light, green light, and red light.

The lower electrode layer 355 may include a metal with excellent electrical conductivity. The lower electrode layer 355 may include a bonding metal layer. For example, the lower electrode layer 355 may include bonding metal such as Sn or In, but is not limited thereto.

In addition, the lower electrode layer 355 may further include an adhesive layer (not shown) such as Cr or Ti to enhance adhesive strength.

The bonding metal layer may be used to electrically connect the lower electrode layer 355 of the semiconductor light emitting device 350 to the second wiring 320 and/or the pad 330.

Additionally, in the embodiment, an upper electrode layer 358 may be provided on the upper side of the light emitting part 354. The upper electrode layer 358 is a transparent member that transmits light and may include, for example, ITO. Additionally, the upper electrode layer 358 may include an ohmic metal layer.

The embodiment includes a passivation layer 356 to block leakage current flowing on the surface of the light emitting part 354, prevents electrical short circuit between a first conductivity type semiconductor layer 351 and the second conductivity type semiconductor layer 353, and the light emitting device 350 may be easily guided to the assembly hole 341. For example, the passivation layer 356 is disposed on the remaining area except the lower side of the light emitting device 350, so that the light emitting device 350 may be easily guided to the assembly hole 341 by a magnetic material during self-assembly. The passivation layer 356 may be formed of an inorganic insulating material, but is not limited thereto.

The passivation layer 356 may include a recess 356R exposing the upper electrode layer 358, and the upper wiring electrode 370 may be electrically connected to the exposed upper electrode layer 358.

Although not shown, a magnetic layer may be provided so that the light emitting device 350 is moved by a magnetic material. The magnetic layer may be provided below or above the light emitting part 354. For example, the magnetic layer may be included in the lower electrode layer 355, but the present invention is not limited thereto. The magnetic layer may include, but is not limited to, a nickel (Ni) layer.

The light emitting device 350 of the embodiment may be a Micro-LED with a micro-scale size or a Nano-LED with a nano-scale size, but is not limited thereto. The light emitting device 350 of the embodiment may be cylindrical, square, oval, plate-shaped, etc., but is not limited thereto.

One of the technical objects of the embodiment is to solve the problem of low self-assembly rate due to non-uniformity of DEP force in self-assembly method using dielectrophoresis (DEP).

In addition, one of the technical objects of the embodiment is to solve the problem of a decrease in the lighting rate due to a decrease in the electrical contact characteristics between the electrodes of the self-assembly light emitting device and the predetermined panel electrode.

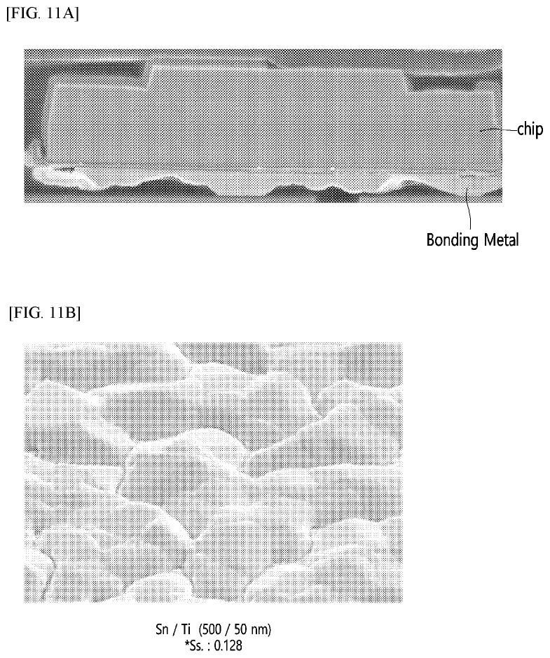

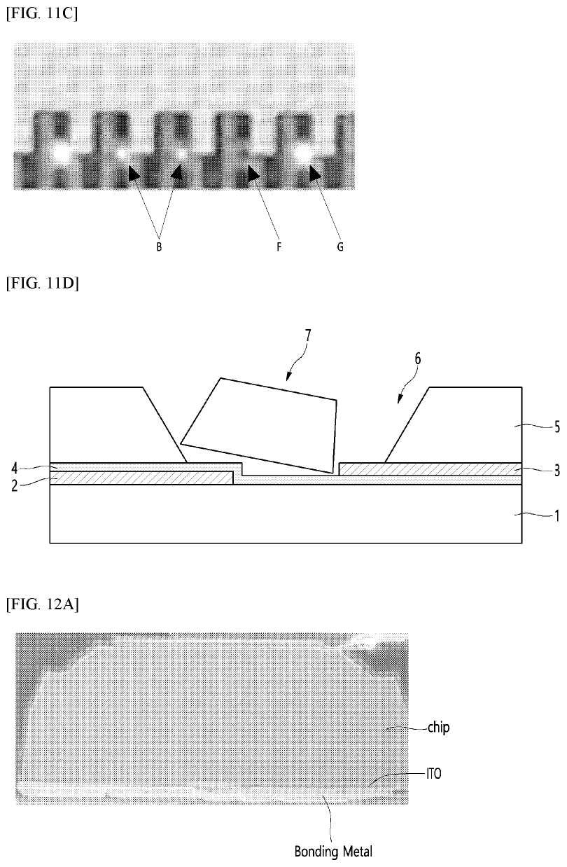

FIGS. 11A to 11D show data based on internal technology related to the display panel.

Specifically, FIG. 11A is a photo of a focused ion beam (FIB) of a light emitting device (chip) and a bonding metal in a display panel according to an internal technology, and FIG. 11B is a photo of a surface image of a bonding metal according to an internal technology.

As shown in FIGS. 11A and 11B, the rear bonding metal in the light emitting device according to the internal technology has poor surface morphology, and the contact characteristics between the rear bonding metal of the light emitting device and the panel wiring are poor, resulting in lighting defects.

For example, FIG. 11C shows lighting data on a display panel according to internal technology.

According to internal technology, poor lighting (B: Bad) or no lighting (F: Fail) is occurring due to defects in the surface characteristics of the rear bonding metal, and good lighting (G: Good) is not achieved, the lighting rate was studied to be at the level of 93.94%.

In internal technology, the electrode layer of the light emitting device may be made of materials such as Ti, Cu, Pt, Ag, and Au, when a bonding metal made of Sn or In, etc. is formed on the electrode layer of this material, the surface becomes uneven due to agglomeration.

Meanwhile, in internal technology, the deposition speed was increased to improve the surface characteristics of the bonding metal, even if the agglomeration phenomenon was partially alleviated, another problem was discovered in which the grain size became smaller as the deposition rate increased and the contact force decreased, and the problem of improving the surface properties of the bonding metal was not easy.

Next, FIG. 11D is a diagram showing the tilt phenomenon that occurs during self-assembly of the internal technology.

According to internal technology, the dielectric layer 4 is disposed on the assembly electrodes 2 and 3 on the assembly substrate 1, and self-assembly of the light emitting device 7 was performed using dielectrophoresis force in the assembly hole 7 defined by the assembly partition wall 5. However, according to internal technology, the problem of self-assembly not being properly performed due to the dielectrophoretic force being dispersed or weakened and tilt within the assembly hole (7) was studied.

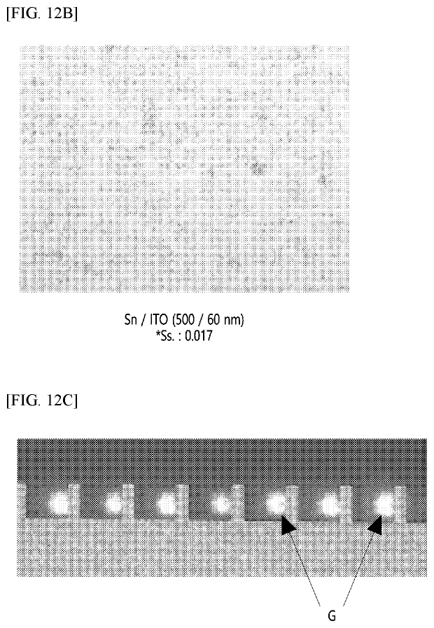

Next, FIGS. 12A to 12C show data on a micro LED display according to an embodiment.

Specifically, FIG. 12A is a FIB photograph of a semiconductor light emitting device applied to a micro led display according to an embodiment, and FIG. 12B is a photograph of the surface image of the bonding metal in FIG. 12A.

According to an example, there is a technical effect of significantly improving the surface morphology of the rear bonding metal by forming a translucent electrode layer between the epitaxial layer (GaN) of the semiconductor light emitting device (chip) and the lower bonding metal. Accordingly, according to the embodiment, the contact characteristics between the rear metal of the light emitting device and the panel wiring are significantly improved, resulting in a technical effect of solving lighting defects.

For example, FIG. 12C shows lighting data from a display panel according to an embodiment. According to the example, lighting defects were prevented by improving the surface properties of the rear metal, and good lighting (G: Good) was achieved, thereby solving the problem of weak lighting or no lighting.

In the embodiment, the translucent electrode layer 357 may be formed including at least one of ITO (indium tin oxide), IAZO (indium aluminum zinc oxide), IZO (indium zinc oxide), IZTO (indium zinc tin oxide), IGZO (indium gallium zinc oxide), IGTO (indium gallium tin oxide), AZO (aluminum zinc oxide), ATO (antimony tin oxide), GZO (gallium zinc oxide), IZON (IZO Nitride), AGZO (Al—Ga ZnO), or IGZO (In—Ga ZnO), but is not limited to these materials.

For example, FIGS. 12A to 12C are experimental embodiments using ITO as the material for the translucent electrode layer 357, but the embodiments are not limited thereto.

In the embodiment, the translucent electrode layer 357 may be formed thinner than the lower electrode layer 355.

For example, the translucent electrode layer 357 may be formed to be 100 nm or less. Additionally, the translucent electrode layer 357 may be formed to be 80 nm or less. Additionally, the translucent electrode layer 357 may be formed to be 60 nm or less.

Additionally, the translucent electrode layer 357 may be formed to be 10 nm or more. Additionally, the translucent electrode layer 357 may be formed to be 20 nm or more. Additionally, the translucent electrode layer 357 may be formed to be 30 nm or more.

According to internal research, by making the surface of the translucent electrode layer 357 hydrophilic, the surface properties of the lower electrode layer 355 formed on the translucent electrode layer 357 were significantly improved and formed uniformly without agglomeration.

Since the translucent electrode layer 357 according to the embodiment has a higher melting point than that of the bonding metal, there is a special technical effect in that there is no reliability problem in the heat compression process.

In the field of electronic devices using conventional light emitting devices, ITO has been used in the upper electrode layer of light emitting devices, but due to the relatively low conductivity of ITO, it has been difficult to be used as a material for the lower electrode layer. In addition, because ITO's physical properties are brittle and weak against impact, there were technical barriers to using it as a bonding metal material that undergoes a heat compression process.

Meanwhile, according to the embodiment, the contact force with the Sn solder layer, which is the lower electrode layer, may be improved by treating the translucent electrode layer 357 with O₂ plasma or Ar plasma, and there is a technical effect of improving the reliability of the translucent electrode layer 357. In addition, as the surface of ITO becomes hydrophilic through O₂ plasma or Ar plasma treatment, the surface characteristics of the lower electrode layer 355 formed on the translucent electrode layer 357 are significantly improved, resulting in the technical effect of forming it uniformly without agglomeration.

Specifically, according to the embodiment, after assembly using a self-assembly method, the p-type semiconductor layer and the n-type semiconductor layer of the light emitting device chip are connected to light. At this time, in the conventional internal technology, the basic characteristics of the rear metal (Sn) for lighting are formed to be uneven after deposition. In these conventional chips, the area connected to the lighting wiring is small, so the light often becomes weak or does not light up after lighting.

However, the vertical chip with a flat structure to which the embodiment is applied is in overall contact with the lower lighting wiring electrode on its surface, so it has excellent electrical contact and has the technical effect of significantly improving lighting yield.

In addition, according to the light emitting device and the display device including the same according to the embodiment, the self-assembly method using dielectrophoresis (DEP) has the technical effect of solving the problem of low self-assembly rate due to non-uniformity of DEP force.

For example, in a self-assembly method using dielectrophoretic forces using electric and magnetic fields in a fluid, the DEP force acting on the chip is generated as the dielectric constant increases.

In the embodiment, the translucent electrode provided on the light emitting device chip has a dielectric constant and thus serves as a dielectric film, so there is a heterogeneous and special technical effect that may improve the assembly rate by improving the DEP force.

Also, in dielectrophoresis, DEP force is concentrated at the corners, but the bonding metal in conventional LED chips protrudes unevenly and the DEP force is biased in one direction, increasing the possibility of the LED chip being tilted.

On the other hand, the light emitting device to which the example is applied has the technical effect of significantly improving the assembly rate of the light emitting device chip into the assembly hole because the DEP force at the bottom of the light emitting device chip is evenly distributed due to the lower electrode layer having a flat surface characteristic due to the translucent electrode layer.

In addition, in the conventional internal technology, the rear metal of the light emitting device chip has a tendency to clump up when placed on top of other metals, so the surface becomes uneven, and even if it enters the assembly hole, the contact area is small and it easily falls off, reducing the assembly rate.

On the other hand, by forming the bonding metal formed on the rear side flat, if the rear side of the light emitting device assembled in the assembly hole by an electric field is flat inside the assembly hole, the contact area increases and becomes stable, and there is a technical effect of improving the assembly rate.

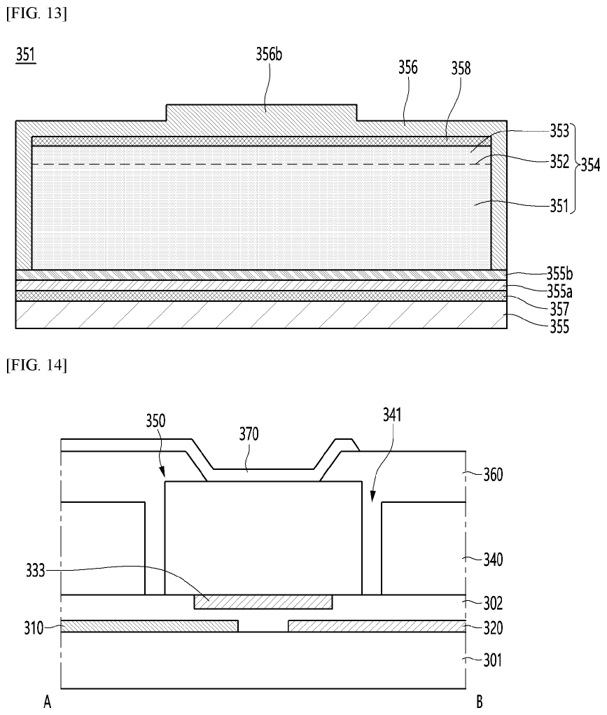

FIG. 13 is a cross-sectional view of the second semiconductor light emitting device 351 applied to the display panel according to the embodiment.

The second semiconductor light emitting device 351 may adopt the technical features of the semiconductor light emitting device 350 described based on FIG. 10.

For example, the second light emitting device 351 may include a light emitting part 354, a lower electrode layer 355, and a passivation layer 356. Additionally, the embodiment may include a translucent electrode layer 357 between the lower electrode layer 355 and the light emitting part 354. Hereinafter, the main technical features of the second light emitting device 351 will be described.

The second light emitting device 351 may further include an adhesive metal layer 355b between the light emitting part 354 and the translucent electrode layer 357. The adhesive metal layer 355b may be Cr, Ti, etc., but is not limited thereto.

The second light emitting device 351 may be provided with a magnetic layer 355a including a nickel (Ni) layer to be moved by a magnetic material. The magnetic layer 355a may be provided on the lower side of the light emitting part 354, but this is not limited.

In the second light emitting device 351, the passivation layer 356 may include a protruding passivation layer 356b. Some of the passivation layer 356 may be removed to expose the upper electrode layer 358, thereby enabling electrical connection with the upper wiring electrode 370.

In the second light emitting device 351, the protruding passivation layer 356b has the technical effect of improving the assembly rate by forming a DEP force at the center of the light emitting device by being disposed in the central area of the light emitting part 354.

Next, FIG. 14 is a cross-sectional view of a second display device according to an embodiment.

The second display device shown in FIG. 14 may adopt the technical features of the display device according to the embodiment shown in FIG. 7, the description will focus on the main features of the second display device shown in FIG. 14.

Referring to FIG. 14, the second display device may include a first wire 310, a second wire 320, and a light emitting device 350, a second pad 333 may be included between the first wire 310 and the second wire 320.

The first wiring 310 and the second wiring 320 may be located at the same height.

The light emitting device 350 may be electrically connected to the second pad 333.

In the embodiment, the translucent electrode 357 provided in the light emitting device 350 has a dielectric constant and thus serves as a dielectric film, thereby improving the DEP force and having a special technical effect of improving the assembly rate.

In addition, the light emitting device 350 to which the embodiment is applied has the technical effect of significantly improving the assembly rate of the light emitting device chip in the assembly hole by distributing the DEP force at the bottom of the light emitting device chip evenly due to the lower electrode layer 355 having a flat surface characteristic due to the translucent electrode layer 357.

In addition, according to the embodiment, there is a technical effect of significantly improving the surface morphology of the rear bonding metal by forming a translucent electrode layer between the epi layer (GaN) of the light emitting device 350 and the lower bonding metal. Accordingly, according to the embodiment, the contact characteristics between the rear metal of the light emitting device and the second pad 333 of the panel are significantly improved, resulting in a technical effect of solving lighting defects.

The above detailed description should not be construed as restrictive in any respect and should be considered illustrative. The scope of the embodiments should be determined by reasonable interpretation of the appended claims, and all changes within the equivalent scope of the embodiments are included in the scope of the embodiments.

### INDUSTRIAL APPLICABILITY

The embodiment may be adopted in the field of displays that display images or information.

The embodiment may be adopted in the field of displays that display images or information using semiconductor light emitting devices.

The embodiment may be adopted in the field of displays that display images or information using micro- or nano-level semiconductor light emitting devices.

1. A display device having a light emitting device comprising:
a light emitting part including a first conductivity type semiconductor layer, an active layer and a second conductivity type semiconductor layer;
an upper electrode layer disposed on the light emitting part;
a lower electrode layer disposed below the light emitting part;
a translucent electrode layer disposed between the light emitting part and the lower electrode layer; and
a pad electrode disposed below the translucent electrode layer.

2. The display device according to claim 1, wherein a surface of the translucent electrode layer is hydrophilic.

3. The display device according to claim 1, wherein the translucent electrode layer has a higher melting point compared to the lower electrode layer.

4. The display device according to claim 1, wherein the translucent electrode layer is treated with O₂ plasma or Ar plasma.

5. The display device according to claim 1, wherein a thickness of the translucent electrode layer is thinner than a thickness of the lower electrode layer.

6. The display device according to claim 1, wherein the translucent electrode layer comprises at least one of ITO (indium tin oxide), IAZO (indium aluminum zinc oxide), IZO (indium zinc oxide), IZTO (indium zinc tin oxide), IGZO (indium gallium zinc oxide), IGTO (indium gallium tin oxide), AZO (aluminum zinc oxide), ATO (antimony tin oxide), GZO (gallium zinc oxide), IZON (IZO Nitride), AGZO (Al—Ga ZnO) or IGZO (In—Ga ZnO).

7. The display device according to claim 1, wherein the translucent electrode layer is formed with a thickness of 10 nm to 100 nm.

8. The display device according to claim 7, wherein the translucent electrode layer is formed with a thickness of 30 nm to 60 nm.

9. The display device according to claim 1, further comprising an adhesive metal layer between the light emitting part and the translucent electrode layer.

10. The display device according to claim 1, further comprising a magnetic layer between the light emitting part and the translucent electrode layer.

11. The display device according to claim 1, further comprising a passivation layer on the light emitting part,
wherein the passivation layer includes a protruding passivation layer overlapping between a center of the light emitting part and a top and bottom.

12. The display device according to claim 1, further comprising:
a first assembly wiring disposed below the translucent electrode layer; and
a second assembly wiring disposed below the translucent electrode layer and spaced apart from the first assembly wiring.

13. The display device according to claim 13, wherein the second assembly wiring is arranged at a different height from the first assembly wiring.

14. A display device having a light emitting device comprising:
a light emitting part including a first conductivity type semiconductor layer, an active layer and a second conductivity type semiconductor layer;
an upper electrode layer disposed on the light emitting part;
a lower electrode layer disposed below the light emitting part;
a translucent electrode layer disposed between the light emitting part and the lower electrode layer;
a pad electrode disposed below the translucent electrode layer; and
a passivation layer vertically overlapping the light emitting part.

15. The display device according to claim 14, wherein the passivation layer is disposed on the light emitting part, and
wherein the passivation layer includes a protruding passivation layer vertically overlapping a center of the light emitting part.

16. The display device according to claim 14, wherein a surface of the translucent electrode layer is hydrophilic.

17. A display device having a light emitting device comprising:
a light emitting part including a first conductivity type semiconductor layer, an active layer and a second conductivity type semiconductor layer;
an upper electrode layer disposed on the light emitting part;
a lower electrode layer disposed below the light emitting part;
a translucent electrode layer disposed between the light emitting part and the lower electrode layer; and
an adhesive metal layer between the light emitting part and the translucent electrode layer.

18. The display device according to claim 17, wherein the translucent electrode layer is treated with O₂ plasma or Ar plasma.

19. The display device according to claim 17, further comprising:
a pad electrode disposed below the translucent electrode layer; and
a passivation layer vertically overlapping the light emitting part.

20. The display device according to claim 17, wherein a surface of the translucent electrode layer is hydrophilic.
